(19) United States
(12) Patent Application Publication
(10) Pub. No.: US 2024/0114661 A1
(43) Pub. Date: Apr. 4, 2024

(54) THERMAL CONDUCTIVE MEMBER, ELECTRONIC DEVICE, METHOD OF MANUFACTURING ELECTRONIC DEVICE, AND METHOD OF REPLACING THERMAL CONDUCTIVE SHEET IN ELECTRONIC DEVICE

(71) Applicant: Panasonic Intellectual Property Management Co., Ltd., Osaka (JP)

(72) Inventors: Youji SHIRATO, Hokkaido (JP); Norihiro KAWAMURA, Hokkaido (JP)

(21) Appl. No.: 18/473,952

(22) Filed: Sep. 25, 2023

(30) Foreign Application Priority Data
Sep. 29, 2022 (JP) 2022-156721

(51) Int. Cl. H05K 7/20

(52) U.S. Cl. CPC H05K 7/2039

(57) ABSTRACT

A thermal conductive member includes a thermal conductive sheet and an adhesive member. The adhesive member is stacked on a front surface of the thermal conductive sheet. An adhesive force of the adhesive member decreases along with a temperature rise.

### CROSS-REFERENCE TO RELATED APPLICATION

The present application is based upon and claims the benefit of priority to Japanese Patent Application No. 2022-156721, filed on Sep. 29, 2022, the entire contents of which are incorporated herein by reference.

### TECHNICAL FIELD

The present disclosure relates to thermal conductive members, electronic devices, methods of manufacturing the electronic devices, and methods of replacing thermal conductive sheets in the electronic devices. The present disclosure specifically relates to a thermal conductive member including a thermal conductive sheet, an electronic device including the thermal conductive member, a method of manufacturing the electronic device, and a method of replacing the thermal conductive sheet in the electronic device.

### BACKGROUND ART

JP 2019-067801 A (hereinafter referred to as “Document 1”) discloses a power module including a base plate, a ceramic insulating substrate bonded to the base plate, a semiconductor element bonded to the ceramic insulating substrate, and a heat dissipation component, and the heat dissipation component is attached via a heat dissipation sheet to the base plate of the power module.

### SUMMARY

It is an object of the present disclosure to provide a thermal conductive member, an electronic device, a method of manufacturing the electronic device, and a method of replacing a thermal conductive sheet in the electronic device which are configured to, when the thermal conductive sheet is laid between a heat generator and a heat radiator, suppress the thermal conductive sheet from being positionally displaced with respect to the heat generator and the heat radiator and which are configured to make the thermal conductive sheet easily detachable when the thermal conductive sheet is to be detached from between the heat generator and the heat radiator.

A thermal conductive member according to an aspect of the present disclosure includes a thermal conductive sheet and an adhesive member. The adhesive member is stacked on a front surface of the thermal conductive sheet. An adhesive force of the adhesive member decreases along with a temperature rise.

An electronic device according to an aspect of the present disclosure includes a heat generator, a heat radiator, a thermal conductive sheet, and an adhesive member. The thermal conductive sheet lies between the heat generator and the heat radiator. The adhesive member lies between the thermal conductive sheet and the heat generator or the heat radiator. An adhesive force of the adhesive member decreases along with a temperature rise.

A method of manufacturing an electronic device according to an aspect of the present disclosure is a method of manufacturing an electronic device including a heat generator, a heat radiator, and a thermal conductive sheet lying between the heat generator and the heat radiator. The method of manufacturing the electronic device includes laying an adhesive member between the thermal conductive sheet and the heat generator or the heat radiator. An adhesive force of the adhesive member decreases along with a temperature rise.

A method of replacing a thermal conductive sheet in an electronic device according to an aspect of the present disclosure is a method of replacing a thermal conductive sheet in an electronic device including: a heat generator; a heat radiator; the thermal conductive sheet lying between the heat generator and the heat radiator; and an adhesive member lying between the thermal conductive sheet and the heat generator or the heat radiator, an adhesive force of the adhesive member decreasing along with a temperature rise. The method includes, after a temperature of the adhesive member increased by heat generated by the heat generator during use of the electronic device reduces the adhesive force of the adhesive member, detaching the thermal conductive sheet from the electronic device, and laying a new thermal conductive sheet different from the thermal conductive sheet between the heat generator and the heat radiator.

### BRIEF DESCRIPTION OF THE DRAWINGS

The figures depict one or more implementation in accordance with the present teaching, by way of example only, not by way of limitations. In the figures, like reference numerals refer to the same or similar elements.

FIGS. 1A to 1D are each a schematic sectional view of a thermal conductive member according to an aspect of the present embodiment;

FIGS. 2A to 2C are each a schematic sectional view of an electronic devices according to an aspect of the present embodiment;

FIGS. 3A to 3C are schematic sectional views of an example of steps for producing an electronic device according to an aspect of the present embodiment;

FIGS. 4A to 4C are schematic sectional view of another example of steps for producing an electronic device according to an aspect of the present embodiment; and

FIGS. 5A to 5E are schematic views of an example of steps for replacing a thermal conductive sheet in the electronic devices according to an aspect of the present embodiment.

### DETAILED DESCRIPTION

1. Overview

A thermal conductive member, an electronic device, a method of manufacturing the electronic device, and a method of replacing a thermal conductive sheet in the electronic device of an embodiment of the present disclosure will be described below. Note that the following embodiment is a mere example of various embodiments of the present disclosure. The embodiment to be described below may be readily modified in various manners depending on design without departing from the scope of the present disclosure. Figures to be described below are schematic views, and the ratio of dimensions of components does not necessarily reflect actual dimensional ratios.

First of all, how the inventors developed the thermal conductive member and the electronic device of the present disclosure will be described.

The inventors independently conducted research on a power module equipped with a heat dissipation component as the one disclosed in Document 1 and found that when a thermal conductive sheet is brought into contact with a heat radiator as the heat dissipation component or a heat generator as the power module at the time of laying the thermal conductive sheet between the heat radiator and the heat generator, the thermal conductive sheet may slip on a front surface of the heat radiator or the heat generator, and thus, disposing the thermal conductive sheet at a correct position may be difficult. When the thermal conductive sheet is bonded to the heat radiator or the heat generator to prevent positional displacement, the thermal conductive sheet may be difficultly peeled off from the heat radiator or the heat generator, for example, when the thermal conductive sheet which has deteriorated is to be replaced, and if the thermal conductive sheet is forcibly peeled off, the thermal conductive sheet may be damaged, and part of the thermal conductive sheet may remain on the heat radiator or the heat generator.

Therefore, the inventors conducted intensive study to solve this problem and consequently accomplished the thermal conductive sheet of the present disclosure.

A thermal conductive member 10 according to the present embodiment includes a thermal conductive sheet 1 and an adhesive member 2. The adhesive member 2 is stacked on a front surface of the thermal conductive sheet 1. An adhesive force of the adhesive member 2 decreases along with a temperature rise. Thus, to lay the thermal conductive member 10 between a heat generator 4 and a heat radiator 3, the thermal conductive sheet 1 may first of all be bonded to one of the heat generator 4 or the heat radiator 3 via the adhesive member 2, thereby temporarily fixing the thermal conductive sheet 1. This suppresses the thermal conductive sheet 1 from being positionally displaced with respect to the heat generator 4 and the heat radiator 3. Moreover, after the thermal conductive member 10 is laid between the heat generator 4 and the heat radiator 3, the temperature rise due to heat generated by the heat generator 4 reduces adhesion of the adhesive member 2. Therefore, when, for example, for replacement of a thermal conductive sheet 1 which has deteriorated, the thermal conductive sheet 1 is to be detached from between the heat generator 4 and the heat radiator 3, the thermal conductive sheet 1 can be easily detached.

Moreover, an electronic device 100 of the present embodiment includes a heat generator 4, a heat radiator 3, a thermal conductive sheet 1, and an adhesive member 2. The thermal conductive sheet 1 lies between the heat generator 4 and the heat radiator 3. The adhesive member 2 lies between the thermal conductive sheet 1 and the heat generator 4 or the heat radiator 3. An adhesive force of the adhesive member 2 decreases along with a temperature rise. According to the electronic device 100 of the present embodiment, to lay the thermal conductive sheet 1 between a heat generator 4 and a heat radiator 3 at the time of producing the electronic device 100, the thermal conductive sheet 1 may first of all be bonded to at least one of the heat generator 4 or the heat radiator 3 via the adhesive member 2, thereby temporarily fixing the thermal conductive sheet 1. This suppresses the thermal conductive sheet 1 from being positionally displaced with respect to the heat generator 4 and the heat radiator 3. Moreover, when the electronic device 100 is used, the temperature rise due to heat generated by the heat generator 4 reduces adhesion of the adhesive member 2. Therefore, when, for example, for replacement of a thermal conductive sheet 1 which has deteriorated in the electronic device 100, the thermal conductive sheet 1 is to be detached from between the heat generator 4 and the heat radiator 3, the thermal conductive sheet 1 can be easily detached.

2. Details

A thermal conductive member, the electronic device, the method of manufacturing the electronic device, and the method of replacing the thermal conductive sheet in the electronic device of the present embodiment will be specifically described below with reference to the drawings.

[Thermal Conductive Member]

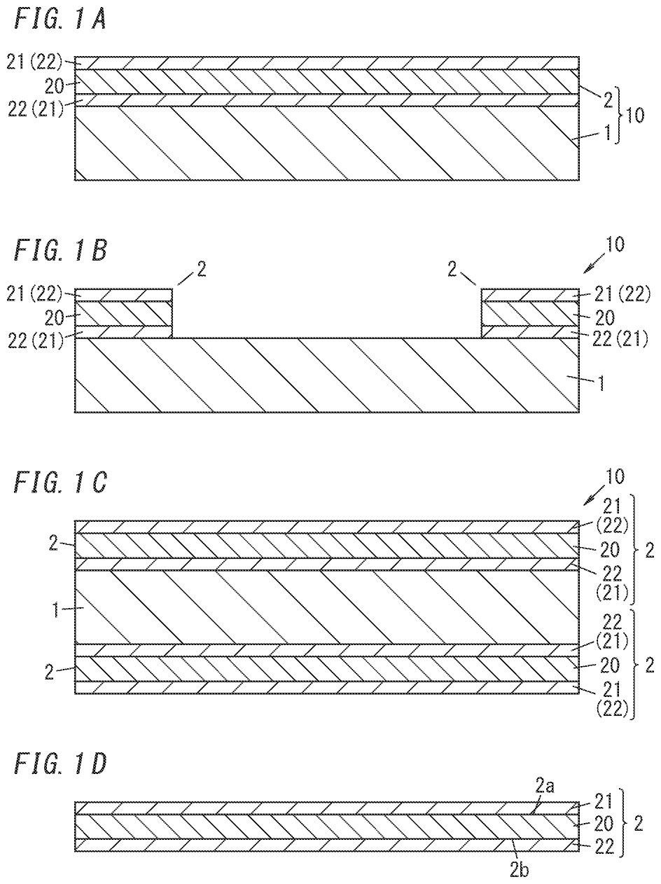

The thermal conductive member 10 according to the present embodiment includes the thermal conductive sheet 1 and the adhesive member 2. The adhesive member 2 of the thermal conductive member 10 is stacked on the front surface of the thermal conductive sheet 1 (see FIG. 1).

<Thermal Conductive Sheet>

The thermal conductive sheet 1 is a thermal conductive material having a sheet shape (thermal interface material: TIM). The thermal conductive sheet 1 may be produced by molding a suitable thermal conductive material into a sheet shape. The thermal conductive material may consist of, for example, a resin component or may be a resin composition obtained by mixing a resin component and ceramic together, a resin composition obtained by mixing a resin component and an inorganic filler, or the like.

The thermal conductive sheet 1 preferably contains graphite. In this case, the thermal conductivity of the thermal conductive member 10 is more easily improved. When the thermal conductive sheet 1 contains graphite, the thermal conductive sheet 1 is, for example, a graphite sheet. The graphite sheet has a structure including a plurality of graphene sheets stacked one on top of another in a thickness direction defined with respect to the graphite sheet. The average thickness of the graphite sheet is, for example, greater than or equal to 1 μm and less than or equal to 1000 μm, preferably greater than or equal to 1 μm and less than or equal to 500 μm, and more preferably greater than or equal to 3 μm and less than or equal to 250 μm.

In the case of the thermal conductive sheet 1 being the graphite sheet, thermal conduction from the heat generator 4 to the heat radiator 3 via the thermal conductive sheet 1 is particularly facilitated. Moreover, the graphite sheet is slippery on the front surface of the heat generator 4 and a front surface of the heat radiator 3. Therefore, in the case of the thermal conductive sheet 1 being the graphite sheet, positional displacement normally easily occurs when the thermal conductive sheet 1 is laid between the heat generator 4 and the heat radiator 3. However, in the present embodiment, even when the thermal conductive sheet 1 is the graphite sheet, the adhesive member 2 suppresses the thermal conductive sheet 1 from being positionally displaced.

Moreover, the graphene sheets in the graphite sheet easily peel off from each other. Therefore, in the case of the thermal conductive sheet 1 being the graphite sheet, the graphene sheets may normally be peeled off from each other when the thermal conductive sheet 1, which is bonded to the heat generator or the heat radiator, is peeled off from the heat generator 4 or the heat radiator 3. Therefore, part of the thermal conductive sheet 1 may remain on the heat generator or the heat radiator. However, in the present embodiment, the adhesion of the adhesive member 2 decreases along with a temperature rise, and therefore, a peel strength of the adhesive member 2 with respect to the heat generator 4 or the heat radiator 3 may decrease to be less than a peel strength between the graphene sheets. Therefore, even when the thermal conductive sheet 1 is the graphite sheet, the graphene sheets are suppressed from peeling off from each other at the time of detaching the thermal conductive sheet 1 from between the heat generator 4 and the heat radiator 3, thereby reducing the possibility of remaining of the thermal conductive sheet 1 on the front surface of the heat generator 4 or the heat radiator 3.

<Adhesive Member>

The adhesive member 2 of the thermal conductive member 10 of the present embodiment is stacked on the front surface of the thermal conductive sheet 1 as described above. The adhesive member 2 is adhesive, and as described above, the adhesive member 2 has the property that its adhesive force decreases along with the temperature rise. After the adhesive force of the adhesive member 2 decreases along with the temperature rise, the adhesive force is preferably not recovered even when the temperature of the adhesive member 2 decreases.

In the present disclosure, the adhesive force of the adhesive member 2 is the 180° peel strength of the adhesive member 2 with respect to an object measured based on JIS Z0237.

The peel strength of the adhesive member 2 measured based on JIS Z0237 after the adhesive member 2 is exposed to an atmosphere at 70° C. for 20 minutes is preferably less than the peel strength of the adhesive member 2 at 25° C. Specifically, after the exposure test of exposing the adhesive member 2 affixed to an object to an atmosphere at 70° C. for 20 minutes, a 180° peel strength X (hereinafter also referred to as a “70° C. peel strength X”) of the adhesive member 2 with respect to the object at 25° C. is measured based on JIS Z0237. Moreover, without the exposure test on the adhesive member 2 affixed to the object, a 180° peel strength Y (hereinafter referred to as a “reference peel strength Y”) of the adhesive member 2 with respect to the object at 25° C. is measured. The 70° C. peel strength X in this case is preferably less than the reference peel strength Y. A ratio of a value obtained by subtracting the 70° C. peel strength X from the reference peel strength Y to the reference peel strength Y may be calculated as a ratio (decrease ratio) by which the adhesive force of the adhesive member 2 has decreased. Thus, the decrease ratio (%) of the adhesive force is expressed by (Y-X)/Y×100.

The reference peel strength Y and the 70° C. peel strength X are more specifically measured, for example, as described below. First of all, two adhesive members 2 having the same configurations are prepared. One of the adhesive members 2 is referred to as a sample #1, and the other of the adhesive members 2 is referred to as a sample #2.

After pressure bonding of the sample #1 to a steel plate as an object made of SUS304 stainless steel and having a thickness of 25 μm at 25° C., the sample #1 is exposed to an atmosphere at 25° C. for 20 minutes. Subsequently, the 180° peel strength of the sample #1 with respect to the steel plate made of SUS304 stainless steel is measured under conditions with a temperature of 25° C., a peel angle of 180°, and a tension rate of 300 mm/min. This peel strength is the reference peel strength Y. Note that the pressure bonding of the adhesive member 2 to the steel plate made of SUS304 stainless steel is achieved by moving a roller having 2 kg back and forth five times on the sample #1.

Moreover, after pressure bonding of the sample #2 to a steel plate as an object made of SUS304 stainless steel and having a thickness of 25 μm under the same conditions as those in the case of the sample #1, the sample #2 is exposed to an atmosphere of 70° C. for 20 minutes. Subsequently, the 180° peel strength of the sample #2 with respect to the steel plate made of SUS304 stainless steel is measured under conditions with a temperature of 25° C., a peel angle of 180°, and a tension rate of 300 mm/min. This peel strength is the 70° C. peel strength X.

The peel strength (70° C. peel strength X) measured based on JIS Z0237 after the adhesive member 2 is exposed to an atmosphere at 70° C. for 20 minutes is preferably less than the peel strength (reference peel strength Y) of the adhesive member 2 at 25° C. by 75% or more. That is, the decrease ratio of the adhesive force of the adhesive member 2 is preferably greater than or equal to 75%. In this case, even when the thermal conductive sheet 1 is bonded to the heat generator 4 or the heat radiator 3 via the adhesive member 2, the thermal conductive sheet 1 is more easily peeled off from the heat generator 4 or the heat radiator 3 after the temperature rise of the adhesive member 2. The decrease ratio of the adhesive force of the adhesive member 2 is more preferably greater than or equal to 85%, and much more preferably greater than or equal to 95%. Note that the steel plate made of SUS304 stainless steel is used as the object for measurement of the reference peel strength and the 70° C. peel strength in the above description, but this description does not hinder application of the thermal conductive member 10 and the adhesive member 2 of the present disclosure to an object other than SUS304 stainless steel.

The adhesive member 2 includes, for example, an adhesive (hereinafter also referred to as a “thermal releasable adhesive”) whose adhesive force decreases along with the temperature rise. The thermal releasable adhesive includes, for example, an adhesive resin component (hereinafter also referred to as an “adhesive component”). The adhesive component includes, for example, at least one type of resin selected from the group consisting of a rubber-based resin, an acryl-based resin, a vinyl alkyl ether-based resin, a silicone-based resin, a polyester-based resin, a polyamide-based resin, a urethane-based resin, a fluorine-based resin, and a styrene-diene block copolymer-based resin. The thermal releasable adhesive may further contain a foaming agent in addition to the adhesive component. The foaming agent is a component thermally expandable as a temperature increases. In the case of the thermal releasable adhesive containing the foaming agent, the foaming agent foams to expand when the temperature of the adhesive member 2 increases, thereby covering a front surface of the adhesive component. This forms recesses and projections on the front surface of the adhesive component, thereby reducing the contact area of the adhesive member 2 to the object. Therefore, in the case of the thermal releasable adhesive containing the foaming agent, the adhesion of the adhesive member 2 is easily reduced. As the foaming agent, an appropriate thermally expandable material may be employed. Examples of the thermally expandable material include thermally expandable microspheres. Examples of the thermally expandable microspheres include microspheres enclosing, in their elastic shells, a substance, such as isobutane, propane, and pentane, which is easily gasified by heating to expand. Examples of a substance forming the shells include vinylidene chloride-acryonitrile copolymer, polyvinyl alcohol, polyvinyl butyral, polymethyl methacrylate, polyacrylonitrile, polyvinylidene chloride, and polysulfone. Note that the foaming agent is not limited to these examples and may be an inorganic foaming agent, an organic foaming agent, or the like.

The thermal releasable adhesive may include an appropriate additive, for example, at least one kind of additive selected from the group consisting of a cross-linker, a tackifier, a plasticizer, a filler, and an anti-aging agent.

The adhesive member 2 includes, for example, an adhesive layer (hereinafter referred to as a “thermal releasable adhesive layer”) produced from a thermal releasable adhesive. The adhesive member 2 may consist of a single thermal releasable adhesive layer (not shown).

The adhesive member 2 may preferably include a base member 20 and a thermal releasable adhesive layer stacked on the base member 20. For example, the adhesive member 2 preferably includes the base member 20, a first adhesive layer 21, and a second adhesive layer 22, and the adhesive force of at least one of the first adhesive layer 21 or the second adhesive layer 22 preferably decreases along with the temperature rise. That is, at least one of the first adhesive layer 21 or the second adhesive layer 22 is preferably the thermal releasable adhesive layer. The first adhesive layer 21 is a layer stacked on a first surface 2a of the base member 20, and the second adhesive layer 22 is a layer stacked on a second surface 2b which is a surface on an opposite side of the base member 20 from the first surface 2a (see FIG. 1D).

The base member 20 is used to support, for example, an adhesive layer(s). When the adhesive member 2 includes the first adhesive layer 21 and the second adhesive layer 22, the base member 20 can support the first adhesive layer 21 and the second adhesive layer 22. As the base member 20, a material as an appropriate support member is at least employed. The base member 20 is not particularly limited. Examples of the material include paper; fiber-based base members such as cloth and unwoven cloth; metal-based base members such as a metal foil and a metal plate; plastic-based base members; and rubber-based base members.

When the adhesive member 2 includes the base member 20, the first adhesive layer 21, and the second adhesive layer 22, the adhesive force of at least one of the first adhesive layer 21 or the second adhesive layer 22 preferably decreases along with the temperature rise. In this case, after the thermal conductive sheet 1 is bonded to the heat generator 4 or the heat radiator 3 via the adhesive member 2, increasing the temperature of the adhesive member 2 enables the adhesive member 2 to be easily peeled off from the heat generator 4 or the heat radiator 3. Note that when the adhesive force of the first adhesive layer 21 decreases along with the temperature rise, the adhesive force of the second adhesive layer 22 does not have to decrease along with the temperature rise; when the adhesive force of the second adhesive layer 22 decreases along with the temperature rise, the adhesive force of the first adhesive layer 21 does not have to decrease along with the temperature rise; or both the adhesive force of the first adhesive layer 21 and the adhesive force of the second adhesive layer 22 may decrease along with the temperature rise.

More preferably, the adhesive force of the first adhesive layer 21 decreases along with the temperature rise, and the second adhesive layer 22 is affixed to the thermal conductive sheet 1. That is, the first adhesive layer 21 is preferably the thermal releasable adhesive layer. In this case, when the thermal conductive sheet 1 is bonded to the heat generator 4 or the heat radiator 3 via the adhesive member 2, the first adhesive layer 21 is bonded to the heat generator 4 or the heat radiator 3. In this state, when the temperature of the adhesive member 2 increases, the adhesive force of the first adhesive layer 21 decreases, and thereby, the first adhesive layer 21 is easily peelable from the heat generator 4 or the heat radiator 3. That is, the adhesive member 2 is easily peelable from the heat generator 4 or heat radiator 3. This further reduces the possibility of the adhesive member 2 remaining on the heat generator 4 or the heat radiator 3.

When the first adhesive layer 21 is the thermal releasable adhesive layer, the first adhesive layer 21 is produced from, for example, the thermal releasable adhesive described above. When the first adhesive layer 21 is the thermal releasable adhesive layer, the second adhesive layer 22 may be the thermal releasable adhesive layer but is preferably not the thermal releasable adhesive layer. That is, preferably, the adhesive force of the second adhesive layer 22 does not decrease or hardly decreases along with the temperature rise. In this case, the second adhesive layer 22 is produced from, for example, an adhesive whose adhesive force does not decrease or hardly decreases along with the temperature rise. The adhesive contains, for example, the adhesive component described above and contains no foaming agent. Examples of a commercially available product of the adhesive member 2 having the property as described above specifically include, but are not limited to, a thermally peelable sheet (product name REVALPHA (registered trademark)) manufactured by Nitto Denko Corporation and a temperature-sensitive adhesive sheet (product name Intelimer (registered trademark) tape) manufactured by Nitta Corporation.

Preferable aspects of the configuration of the thermal conductive member 10 will be described with reference to the drawings.

In FIG. 1A, one adhesive member 2 is stacked on one thermal conductive sheet 1, but this should not be construed as limiting. For example, two or more adhesive members 2 may be disposed on one thermal conductive sheet 1. For example, as shown in FIG. 1C, on the front surface of the thermal conductive sheet 1, one adhesive member 2 (here, referred to as a “first adhesive member”) is stacked, and on a surface (i.e., a back surface) on an opposite side of the thermal conductive sheet 1 from the front surface, one adhesive member 2 (here, referred to as a “second adhesive member”) different from the first adhesive member may be stacked.

In the thermal conductive member 10, the adhesive member 2 may be disposed all over the front surface of the thermal conductive sheet 1 or may be disposed on part of the front surface of the thermal conductive sheet 1. For example, as shown in FIG. 1B, the adhesive member 2 may be disposed to overlap both end portions of the front surface of the thermal conductive sheet 1. In this case, even when the thermal conductive sheet 1 of the thermal conductive member 10 is bonded to the heat generator 4 or the heat radiator 3 via the adhesive member 2, good thermal conduction between the heat generator 4 or the heat radiator 3 and the thermal conductive sheet 1 is easily maintained.

The thickness of the thermal conductive sheet 1 of the thermal conductive member 10 may accordingly be adjusted and is, for example, greater than or equal to 1 μm and less than or equal to 1000 μm, preferably greater than or equal to 1 μm and less than or equal to 500 μm, and more preferably greater than or equal to 3 μm and less than or equal to 250 μm. The thickness of the adhesive member 2 may accordingly be adjusted and is, for example, greater than or equal to 1 μm and less than or equal to 1000 μm, preferably greater than or equal to 1 μm and less than or equal to 500 μm, and more preferably greater than or equal to 3 μm and less than or equal to 250 μm. When the adhesive member 2 includes the first adhesive layer 21 and the second adhesive layer 22, the thickness of the first adhesive layer 21 is greater than or equal to 1 μm and less than or equal to 1000 μm, preferably greater than or equal to 1 μm and less than or equal to 500 μm, and more preferably greater than or equal to 3 μm and less than or equal to 250 μm. The thickness of the second adhesive layer 22 may be the same as, or different from, that of the first adhesive layer.

The thermal conductive member 10 may have a member(s) other than the members described above without departing from the scope of the present disclosure.

The thermal conductive member 10 of the present embodiment lies between the heat generator 4 and the heat radiator 3 as described above, thereby facilitating thermal conduction from the heat generator 4 to the heat radiator 3. Note that the thermal conductive member 10 may be applied to any application other than the application described above.

[Electronic Device]

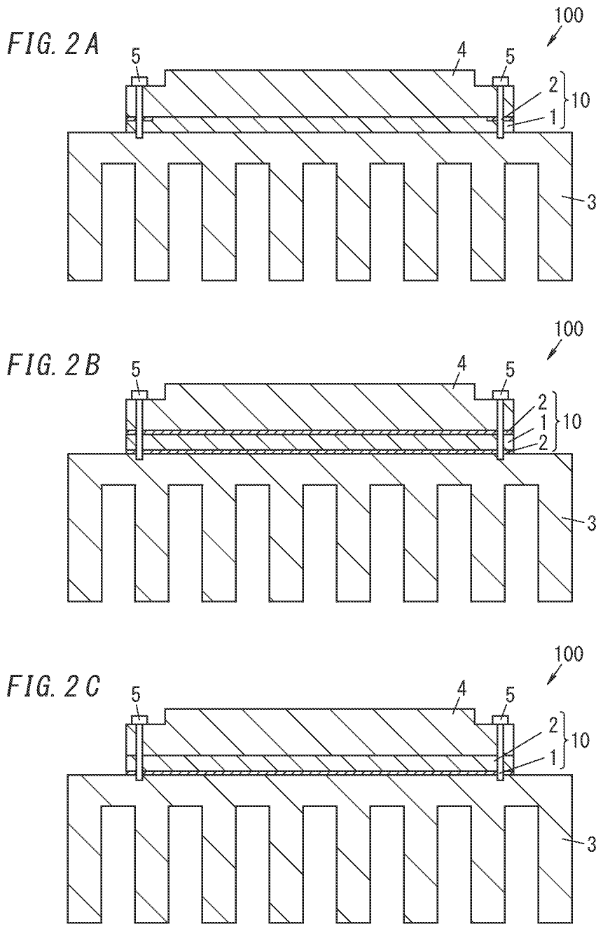

The electronic device 100 of the present embodiment includes a heat generator 4, a heat radiator 3, a thermal conductive sheet 1, and an adhesive member 2. The thermal conductive sheet 1 lies between the heat generator 4 and the heat radiator 3. The adhesive member 2 lies between the thermal conductive sheet 1 and the heat generator 4 or the heat radiator 3 (see FIGS. 2A to 2C). An adhesive force of the adhesive member 2 decreases along with a temperature rise. Thus, in the electronic device 100 of the present embodiment, laying the thermal conductive sheet 1 between the heat generator 4 and the heat radiator 3 enables the thermal conductive sheet 1 to be bonded to the heat generator 4 or the heat radiator 3 via the adhesive member 2 and enables the thermal conductive sheet 1 to be easily peeled off from the heat generator 4 or the heat radiator 3. Note that saying that the adhesive member 2 “lies between the thermal conductive sheet 1 and the heat generator 4 or the heat radiator 3” does not hinder that an adhesive member 2 is disposed between the thermal conductive sheet 1 and the heat generator 4 and another adhesive member 2 is disposed between the thermal conductive sheet 1 and the heat radiator 3. In this case, on the front surface and the back surface of the thermal conductive sheet 1, the respective adhesive members 2 are stacked (see FIG. 2C).

In the electronic device 100 of the present embodiment, the thermal conductive sheet 1 lies between the heat generator 4 and the heat radiator 3, thereby enabling heat generated from the heat generator 4 to be transmitted to the heat radiator 3.

The thermal conductive sheet 1 may be the same as the thermal conductive sheet 1 described for the thermal conductive member 10. Therefore, for the detailed description of the thermal conductive sheet 1 in the electronic device 100, the description of the thermal conductive sheet 1 of the thermal conductive member 10 may be referred to. A description redundant with the description of the thermal conductive sheet 1 of the thermal conductive member 10 will accordingly be omitted by using the same reference sign as that of the thermal conductive member 10.

The adhesive member 2 may be the same as the adhesive member 2 described for the thermal conductive member 10. Therefore, for the description of the adhesive member 2 of the electronic device 100, the description of the adhesive member 2 of the thermal conductive member 10 may be referred to. A description redundant with the description of the adhesive member 2 of the thermal conductive member 10 will accordingly be omitted by using the same reference sign as that of the thermal conductive member 10.

Note that in the electronic device 100, the thermal conductive sheet 1 and the adhesive member 2 may constitute the thermal conductive member 10 described above. That is, the electronic device 100 may include the heat generator 4, the heat radiator 3, and the thermal conductive member 10, and the thermal conductive sheet 1 of the thermal conductive member 10 may lie between the heat generator 4 and the heat radiator 3, and the adhesive member 2 of the thermal conductive member 10 may lie between the thermal conductive sheet 1 and the heat generator 4 or the heat radiator 3. Moreover, the thermal conductive sheet 1 and the adhesive member 2 may be separate members.

The heat generator 4 operates to generate heat. For example, the heat generator 4 generates heat while the electronic device 100 is used. Examples of the heat generator 4 include, but are not limited to, a power device which is a semiconductor element used for controlling supplying electrical energy.

The heat radiator 3 has functions of, for example, receiving heat from a member in the periphery thereof, releasing the heat outside, and controlling thermal runaway of the electronic device 100. Examples of the heat radiator 3 include, but are not limited to, a heat sink used as a cooling component.

That the electronic device 100 according to the present embodiment includes the adhesive member 2 whose adhesion decreases along with the temperature rise can be perceived, as described above, by measuring, based on JIS Z0237, the peel strength of the adhesive member 2 thus heated to check whether or not the peel strength decreases. Moreover, that the electronic device 100 includes the adhesive member 2 whose adhesion decreases along with the temperature rise can be confirmed by observing the external appearance of the adhesive member 2 before the temperature increases and the external appearance of the adhesive member 2 after the temperature increases by using a device such as a microscope. Specifically, since the adhesive member 2 after the temperature increases includes air bubbles which are present near a front surface of the adhesive member 2 and which result from, for example, foaming of the adhesive and the front surface of the adhesive member 2 may thus have a changed shape, occurrence of a change due to the temperature rise can be confirmed by comparing the shape of the adhesive member 2 after the temperature increases with the shape (external appearance) of the adhesive member 2 before the temperature increases.

[Method of Manufacturing Electronic Device]

A method of manufacturing the electronic device 100 according to the present embodiment is a method of manufacturing an electronic device 100 including a heat generator 4, a heat radiator 3, and a thermal conductive sheet 1, and the method includes laying an adhesive member 2 between the thermal conductive sheet 1 and the heat generator 4 or the heat radiator 3. The thermal conductive sheet 1 lies between the heat generator 4 and the heat radiator 3. An adhesive force of the adhesive member 2 decreases along with a temperature rise. The thermal conductive sheet 1 and the adhesive member 2 may respectively be the same as the thermal conductive sheet 1 and the adhesive member 2 described for the thermal conductive member 10. Therefore, for the detailed description of the thermal conductive sheet 1 and the adhesive member 2 in the electronic device 100, the description of the thermal conductive sheet 1 and the adhesive member 2 of the thermal conductive member 10 may be referred to. A description redundant with the description of the thermal conductive sheet 1 and the adhesive member 2 of the thermal conductive member 10 will accordingly be omitted by using the same reference signs as those of the thermal conductive member 10.

The electronic device 100 according to the present embodiment can be produced specifically, for example, in the following way.

First of all, the thermal conductive sheet 1, the adhesive member 2, the heat generator 4, and the heat radiator 3 are prepared. The adhesive member 2 is stacked on the front surface of the thermal conductive sheet 1. Thus, a laminate of the thermal conductive sheet 1 and the adhesive member 2 is produced. In this case, the adhesive member 2 may be stacked all over the front surface of the thermal conductive sheet 1 or may be stacked on part of the thermal conductive sheet 1. Moreover, adhesive members 2 may be stacked on both surfaces, that is, the front surface of the thermal conductive sheet 1 and a surface (back surface) on an opposite side of the thermal conductive sheet 1 from the front surface. As described above, the thermal conductive sheet 1 and the adhesive member 2 may constitute the thermal conductive member 10 described above. That is, the laminate of the thermal conductive sheet 1 and the adhesive member 2 may be the thermal conductive member 10 described above. The thermal conductive sheet 1 and the adhesive member 2 may of course be separate members.

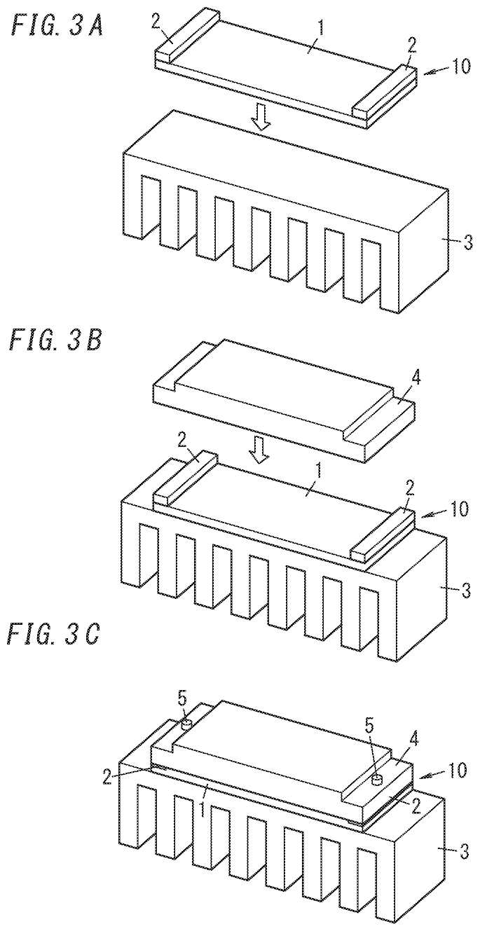

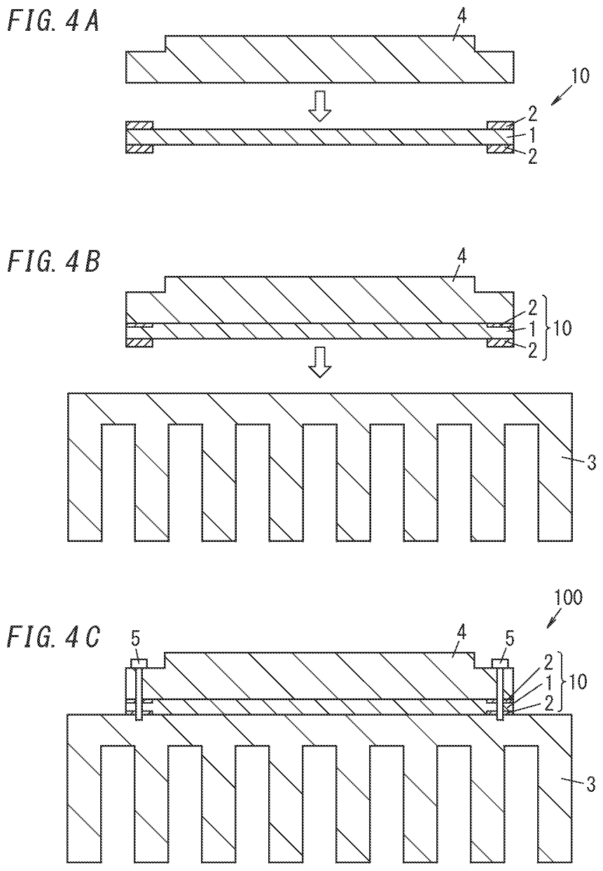

Subsequently, the laminate of the thermal conductive sheet 1 and the adhesive member 2 is disposed to lie between the heat generator 4 and the heat radiator 3. In this case, the adhesive member 2 is disposed to be stacked on at least one of the heat generator 4 or the heat radiator 3 (FIGS. 3A and 3B). In FIGS. 3A and 3B, the adhesive member 2 is disposed to lie between the thermal conductive sheet 1 and the heat generator 4. Thus, the electronic device 100 can be produced in which the thermal conductive sheet 1 and the adhesive member 2 lie between the heat generator 4 and the heat radiator 3 (see FIGS. 3C and 4C). Note that the thermal conductive sheet 1 and the adhesive member 2 can expand and contract when stacked on the heat generator 4 or the heat radiator 3 and compressed, and therefore, the drawings show the thermal conductive sheet 1 absorbing the thickness of the adhesive member 2 and thus being significantly deformed, but the thermal conductive sheet 1 and the adhesive member 2 are not limited to this example.

When adhesive members 2 are stacked on both surfaces, that is, on the front surface and the back surface, of the thermal conductive sheet 1, as shown in FIGS. 4A to 4C, the electronic device 100 can be produced which includes the adhesive member 2 lying between the heat generator 4 and the thermal conductive sheet 1 and the adhesive member 2 lying between the thermal conductive sheet 1 and the heat radiator 3.

The electronic device 100 may have a fixing tool 5, such as a screw, inserted thereinto to couple the heat generator 4 and the heat radiator 3 to each other (see, for example, FIG. 2A). This enables the heat generator 4 and the heat radiator 3 to be fixed to each other by tightening. For example, the fixing tool 5 penetrates, at an end of the heat generator 4, through the heat generator 4, the thermal conductive sheet 1, and the adhesive member 2 and is inserted to an upper portion of the heat radiator 3, thereby coupling the heat generator 4 and the heat radiator 3 to each other. Note that the location and the fixation method of the fixing tool 5 are not limited to the example described above.

Note that to manufacture the electronic device 100, the laminate of the thermal conductive sheet 1 and the adhesive member 2 or the thermal conductive member 10 does not have to be stacked on the heat generator 4 or the heat radiator 3 as described above. For example, to lay the adhesive member 2 between the thermal conductive sheet 1 and the heat generator 4 or the heat radiator 3, the thermal conductive sheet 1 and the adhesive member 2 may be prepared as separate members, and the adhesive member 2 is stacked on the heat generator 4, and then, the thermal conductive sheet 1 may be laid between the adhesive member 2 and the heat radiator 3. Alternatively, the adhesive member 2 may be stacked on the heat radiator 3, and then, the thermal conductive sheet 1 may be laid between the adhesive member 2 and the heat generator 4. Still alternatively, the adhesive member 2 may be disposed on each of the heat generator 4 and the heat radiator 3, and then, the thermal conductive sheet 1 may be stacked on the adhesive member 2 on the heat radiator 3, and subsequently, the adhesive member 2 on the heat generator 4 may be stacked on the thermal conductive sheet 1.

The peel strength of the adhesive member 2 of the electronic device 100 measured based on JIS Z0237 after the adhesive member 2 is exposed to an atmosphere at 70° C. for 20 minutes is preferably less than the peel strength of the adhesive member 2 at 25° C. by 75% or more.

[Method of Replacing Thermal Conductive Sheet in Electronic Device]

Subsequently, a method of replacing the thermal conductive sheet 1 in the electronic device 100 will be described.

The electronic device 100 is an electronic device 100 including a heat generator 4, a heat radiator 3, a thermal conductive sheet 1, and an adhesive member 2. Specifically, the electronic device 100 includes the heat generator 4, the heat radiator 3, the thermal conductive sheet 1 lying between the heat generator 4 and the heat radiator 3, and the adhesive member 2 lying between the thermal conductive sheet 1 and the heat generator 4 or the heat radiator 3, and the adhesive force of the adhesive member 2 decreases along with a temperature rise. That is, the electronic device 100 has the same configuration as that of the electronic device described above. Therefore, for the thermal conductive sheet 1, the adhesive member 2, the heat generator 4, and the heat radiator 3, the configuration described above is accordingly omitted by using the same reference signs as used above.

When the electronic device 100 is used for a certain time period and is then subjected to an operation check, a regular check, maintenance, and the like, the thermal conductive sheet 1 which has deteriorated may have to be replaced. When in the electronic device 100, the thermal conductive sheet 1 is bonded to the heat generator 4 or the heat radiator 3 to suppress the thermal conductive sheet 1 from being positionally displaced, the thermal conductive sheet 1 laid between the heat generator 4 and the heat radiator 3 is normally difficultly peeled off from the heat generator 4 or the heat radiator 3. Therefore, when the thermal conductive sheet 1 is attempted to be peeled off from the heat generator 4 or the heat radiator 3, part, or the entirety, of the thermal conductive sheet 1 may remain on the heat generator 4 or the heat radiator 3. That is, the thermal conductive sheet 1 is not easily detached from the electronic device 100. Therefore, if part of the thermal conductive sheet 1 remains on the heat generator 4 or the heat radiator 3 when the thermal conductive sheet 1 is peeled off from the heat generator 4 or the heat radiator 3, a step of removing the part from the heat generator 4 or the heat radiator 3 is required, and therefore, maintenance of the electronic device 100 is time-consuming.

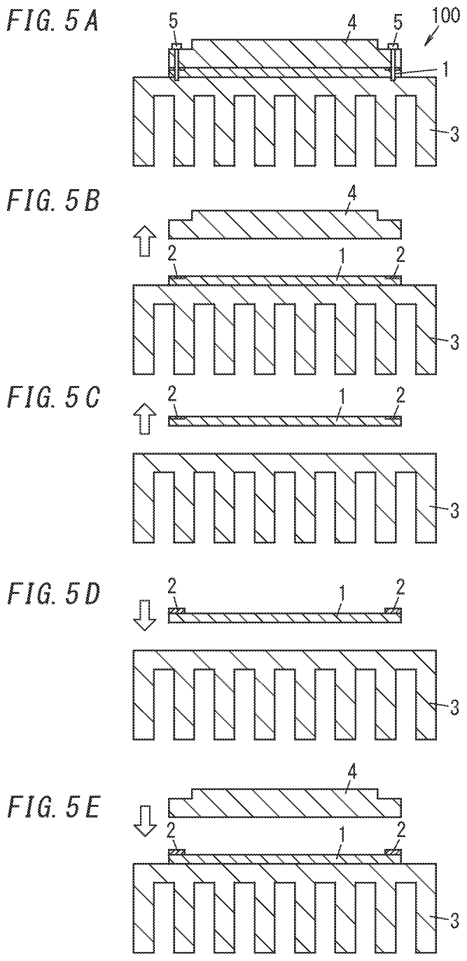

In contrast, the method of replacing the thermal conductive sheet 1 in the electronic device 100 of the present embodiment includes, after heat generated by the heat generator 4 during use of the electronic device 100 increases the temperature of the adhesive member 2 and thus decreases the adhesive force of the adhesive member 2, detaching the thermal conductive sheet 1 from the electronic device 100, and laying a new thermal conductive sheet 1 different from the thermal conductive sheet 1 between the heat generator 4 and the heat radiator 3 (FIGS. 5A to 5E). In the electronic device 100, the heat generated from the heat generator 4 by the use of the electronic device 100 increases the temperature of the adhesive member 2, and as described above, the adhesive force of the adhesive member 2 in the electronic device 100 decreases along with the temperature rise. Thus, the adhesive member 2 lying between the thermal conductive sheet 1 and the heat generator 4 is easily peelable from the thermal conductive sheet 1 and the heat generator 4. The adhesive member 2 lying between the thermal conductive sheet 1 and the heat radiator 3 is easily peelable from the thermal conductive sheet 1 and the heat radiator 3. Therefore, in the method of replacing the thermal conductive sheet 1 of the present embodiment, even when the thermal conductive sheet 1 is peeled off from the heat generator 4 or the heat radiator 3, the possibility of the occurrence of interlayer peeling and the like in the thermal conductive sheet 1 is reduced, and the possibility of part, or the entirety, of the thermal conductive sheet 1 remaining on the heat generator 4 or the heat radiator 3 is reduced. Thus, in the method of replacing the thermal conductive sheet 1 in the electronic device 100 of the present embodiment, the thermal conductive sheet 1 is easily detachable even when the thermal conductive sheet 1 is temporarily fixed to suppress the positional displacement.

In the method of replacing the thermal conductive sheet 1 in the electronic device 100 of the present embodiment, the adhesive member 2 preferably includes the base member 20, the first adhesive layer 21 stacked on the first surface 2a of the base member 20, and the second adhesive layer 22 stacked on the second surface 2b on an opposite side of the base member 20 from the first surface 2a as described above. In this case, the adhesive force of the first adhesive layer 21 preferably decreases along with the temperature rise, and the second adhesive layer 22 is preferably affixed to the thermal conductive sheet 1. Moreover, the adhesive member 2 preferably lie between the thermal conductive sheet 1 and the heat generator 4. In this case, the adhesive member 2 is easily peelable from the heat generator 4, and therefore, the maintenance of the electronic device 100 is more easily performed.

The thermal conductive sheet 1 in the electronic device 100 is exchangeable specifically, for example, in the following way. Note that in the following description, the adhesive member 2 is assumed to include the base member 20, the first adhesive layer 21, and the second adhesive layer 22, the adhesive force of the first adhesive layer 21 decreases along with the temperature rise, and the second adhesive layer 22 is assumed to be affixed to the thermal conductive sheet 1, but the method of replacing the thermal conductive sheet 1 is not limited to this example.

First of all, the heat generator 4 and the heat radiator 3 in the electronic device 100 are disassembled (see FIGS. 5A and 5B). Then, from the heat generator 4 or the heat radiator 3, the thermal conductive sheet 1 is removed. At this time, the thermal conductive sheet 1 lying between the heat generator 4 and the heat radiator 3 is maintained in a state where the thermal conductive sheet 1 is bonded to the base member 20 via the second adhesive layer 22 of the adhesive member 2. In contrast, use of the electronic device 100 causes the heat generator 4 to generate heat, which increases the temperature of the adhesive member 2 and thus reduces the adhesive force of the first adhesive layer 21 of the adhesive member 2, and therefore, the thermal conductive sheet 1 is easily peeled off from the heat generator 4 or the heat radiator 3 (see FIG. 5C).

The thermal conductive sheet 1 after the use of the electronic device 100 is detached, a new thermal conductive sheet 1 different from the thermal conductive sheet 1 is prepared, and the new thermal conductive sheet 1 is disposed on the adhesive member 2 laid on the heat generator 4 or the heat radiator 3 (see FIG. 5D). Subsequently, the heat generator 4 or the heat radiator 3 is disposed to achieve a state where the thermal conductive sheet 1 lies between the heat radiator 3 or the heat generator 4 (see FIG. 5E). Thus, the thermal conductive sheet 1 in the electronic device 100 can be replaced.

When the thermal conductive sheet 1 in the electronic device 100 is replaced, heat generated by the heat generator 4 during use of the electronic device 100 preferably make the temperature of the heat generator 4 reach a temperature higher than or equal to a temperature at which the adhesive force of the adhesive member 2 starts decreasing. In this case, the heat generated by the heat generator 4 during use of the electronic device 100 easily reduces the adhesive force of the adhesive member 2 and easily create a state where the thermal conductive sheet 1 is more easily peeled off. Therefore, the thermal conductive sheet 1 in the electronic device 100 is more easily replaced.

The temperature at which the adhesive force of the adhesive member 2 starts decreasing is calculable by measuring the 180° peel strength of the adhesive member 2 described above with respect to an object. In the present disclosure, a temperature at which the 180° peel strength of the adhesive member 2 with respect to the object measured based on JIS Z0237 is lower than the peel strength (reference peel strength Y) at 25° C. by 75% or more is referred to as the temperature at which the adhesive force of the adhesive member 2 starts decreasing. The temperature at which the adhesive force of the adhesive member 2 starts decreasing is preferably higher than or equal to 50° C. and lower than or equal to 125° C.

The temperature of the heat generator 4 due to the heat generated by the heat generator 4 during use of the electronic device 100 is sensed by using a temperature sensor and the like or is directly measured. The temperature of the heat generator 4 is, for example, 100° C. but is not limited to this example.

### SUMMARY

As can be seen from the embodiment described above, the present disclosure includes the following aspects. In the following description, reference signs in parentheses are provided to clearly show the correspondence relationship to the embodiment.

A thermal conductive member (10) of a first aspect includes a thermal conductive sheet (1) and an adhesive member (2). The adhesive member (2) is stacked on a front surface of the thermal conductive sheet (1). An adhesive force of the adhesive member (2) decreases along with a temperature rise.

According to the first aspect, when the thermal conductive sheet (1) is laid between the heat generator (4) and the heat radiator (3), the thermal conductive sheet (1) is suppressed from being positionally displaced with respect to the heat generator (4) and the heat radiator (3), and the thermal conductive sheet (1) is easily detachable when the thermal conductive sheet (1) is to be detached from between the heat generator (4) and the heat radiator (3).

In a thermal conductive member (10) of a second aspect of the present disclosure referring to the first aspect, the adhesive member (2) includes a base member (20), a first adhesive layer (21), and a second adhesive layer (22). The first adhesive layer (21) is stacked on a first surface (2a) of the base member (20). The second adhesive layer (22) is stacked on a second surface (2b) which is a surface on an opposite side of the base member (20) from the first surface (2a). An adhesive force of at least one of the first adhesive layer (21) or the second adhesive layer (22) decreases along with the temperature rise.

According to the second aspect, after the thermal conductive sheet (1) is bonded to the heat generator (4) or the heat radiator (3) via the adhesive member (2), increasing the temperature of the adhesive member (2) enables the adhesive member (2) to be easily peeled off from the heat generator (4) or the heat radiator (3).

In a thermal conductive member (10) of a third aspect of the present disclosure referring to the second aspect, the adhesive force of the first adhesive layer (21) decreases along with the temperature rise, and the second adhesive layer (22) is affixed to the thermal conductive sheet (1).

According to the third aspect, increasing the temperature of the adhesive member (2) enables the adhesive member (2) affixed to the thermal conductive sheet (1) to be more easily peeled off from the heat generator (4) or the heat radiator (3).

In a thermal conductive member (10) of a fourth aspect of the present disclosure referring to any one of the first to third aspects, the peel strength of the adhesive member (2) measured based on JIS Z0237 after the adhesive member (2) is exposed to an atmosphere of 70° C. for 20 minutes is less than the peel strength of the adhesive member (2) at 25° C. by 75% or more.

According to the fourth aspect, the thermal conductive sheet (1) is more easily detachable when the thermal conductive sheet (1) is to be detached from between the heat generator (4) and the heat radiator (3).

In a thermal conductive member (10) of a fifth aspect of the present disclosure referring to any one of the first to fourth aspects, the thermal conductive sheet (1) contains graphite.

According to the fifth aspect, heat transmission of the thermal conductive member (10) is further improved.

An electronic device (100) of a sixth aspect of the present disclosure includes a heat generator (4), a heat radiator (3), a thermal conductive sheet (1), and an adhesive member (2). The thermal conductive sheet (1) lies between the heat generator (4) and the heat radiator (3). The adhesive member (2) lies between the thermal conductive sheet (1) and the heat generator (4) or the heat radiator (3). An adhesive force of the adhesive member (2) decreases along with a temperature rise.

According to the sixth aspect, when the thermal conductive sheet (1) is laid between the heat generator (4) and the heat radiator (3), the thermal conductive sheet (1) is suppressed from being positionally displaced with respect to the heat generator (4) and the heat radiator (3), and the thermal conductive sheet (1) is easily detachable when the thermal conductive sheet (1) is to be detached from between the heat generator (4) and the heat radiator (3).

In an electronic device (100) of a seventh aspect of the present disclosure referring to the sixth aspect, the adhesive member (2) includes a base member (20), a first adhesive layer (21), and a second adhesive layer (22). The first adhesive layer (21) is on a first surface (20a) of the base member (20). The second adhesive layer (22) is on a second surface (20b) which is a surface of the base member (20) on an opposite side of the first surface (20a). An adhesive force of at least one of the first adhesive layer (21) or the second adhesive layer (22) decreases along with the temperature rise.

According to the seventh aspect, after the thermal conductive sheet (1) is bonded to the heat generator (4) or the heat radiator (3) via the adhesive member (2), increasing the temperature of the adhesive member (2) enables the adhesive member (2) to be easily peeled off from the heat generator (4) or the heat radiator (3).

In an electronic device (100) of an eighth aspect of the present disclosure referring to the seventh aspect, the adhesive force of the first adhesive layer (21) decreases along with the temperature rise, and the second adhesive layer (22) is affixed to the thermal conductive sheet (1).

According to the eighth aspect, increasing the temperature of the adhesive member (2) enables the adhesive member (2) affixed to the thermal conductive sheet (1) to be easily peeled off from the heat generator (4) or the heat radiator (3).

In an electronic device (100) of a ninth aspect of the present disclosure, the adhesive member (2) lies between the thermal conductive sheet (1) and the heat generator (4).

The ninth aspect reduces the possibility that when the thermal conductive sheet (1) is to be peeled off from the heat generator (4), the thermal conductive sheet (1) remains on the heat generator (4).

In a tenth aspect of the present disclosure referring to any one of the sixth to ninth aspects, the peel strength of the adhesive member (2) measured based on JIS Z0237 after the adhesive member (2) is exposed to an atmosphere of 70° C. for 20 minutes is less than the peel strength of the adhesive member (2) at 25° C. by 75% or more.

According to the tenth aspect, the thermal conductive sheet (1) is more easily detachable when the thermal conductive sheet (1) is to be detached from between the heat generator (4) and the heat radiator (3).

In an eleventh aspect of the present disclosure referring to any one of the sixth to tenth aspects, the thermal conductive sheet (1) contains graphite.

According to the eleventh aspect, transmission of heat generated by the heat generator (4) of the electronic device (100) is further improved.

In a method of manufacturing an electronic device of a twelfth aspect of the present disclosure is a method of manufacturing an electronic device (100) including a heat generator (4), a heat radiator (3), and a thermal conductive sheet (1) lying between the heat generator (4) and the heat radiator (3). The method of manufacturing the electronic device (100) includes laying an adhesive member (2) between the thermal conductive sheet (1) and the heat generator (4) or the heat radiator (3). An adhesive force of the adhesive member (2) decreases along with a temperature rise.

The twelfth aspect enables an electronic device (100) to be produced such that after the thermal conductive sheet (1) is bonded to the heat generator (4) or the heat radiator (3) via the adhesive member (2), increasing the temperature of the adhesive member (2) enables the adhesive member (2) to be easily peeled off from the heat generator (4) or the heat radiator (3).

In a method of manufacturing an electronic device according to a thirteenth aspect of the present disclosure referring to the twelfth aspect, the adhesive member (2) includes a base member (20), a first adhesive layer (21), and a second adhesive layer (22). The first adhesive layer (21) is stacked on a first surface (2a) of the base member (20). The second adhesive layer (22) is stacked on a second surface (2b) which is a surface on an opposite side of the base member (20) from the first surface (2a). An adhesive force of at least one of the first adhesive layer (21) or the second adhesive layer (22) decreases along with the temperature rise.

The thirteenth aspect enables an electronic device (100) to be produced such that after the thermal conductive sheet (1) is bonded to the heat generator (4) or the heat radiator (3) via the adhesive member (2), increasing the temperature of the adhesive member (2) enables the adhesive member (2) to be easily peeled off from the heat generator (4) or the heat radiator (3).

In a method of manufacturing an electronic device of a fourteenth aspect of the present disclosure referring to the thirteenth aspect, the adhesive force of the first adhesive layer (21) decreases along with the temperature rise, and the second adhesive layer (22) is affixed to the thermal conductive sheet (1).

The fourteenth aspect enables an electronic device (100) to be produced with a reduced possibility that when the thermal conductive sheet (1) is to be peeled off from the heat generator (4), the thermal conductive sheet (1) remains on the front surface of the heat generator (4) or the heat radiator (3).

In a method of manufacturing an electronic device of a fifteenth aspect of the present disclosure referring to any one of the twelfth to fourteenth aspects, the adhesive member (2) is laid between the thermal conductive sheet (1) and the heat generator (4).

The fifteenth aspect enables an electronic device (100) to be produced with a reduced possibility that when the thermal conductive sheet (1) is to be peeled off from the heat generator (4), the thermal conductive sheet (1) remains on the front surface of the heat generator (4).

In a method of manufacturing an electronic device of a sixteenth aspect of the present disclosure referring to any one of the twelfth to fifteenth aspects, the peel strength of the adhesive member (2) measured based on JIS Z0237 after the adhesive member (2) is exposed to an atmosphere of 70° C. for 20 minutes is less than the peel strength of the adhesive member (2) at 25° C. by 75% or more

The sixteenth aspect enables an electronic device (100) to be produced such that the thermal conductive sheet (1) is more easily detachable when the thermal conductive sheet (1) is to be detached from between the heat generator (4) and the heat radiator (3).

In a method of manufacturing an electronic device of a seventeenth aspect of the present disclosure referring to any one of the twelfth to sixteenth aspects, the thermal conductive sheet (1) contains graphite.

The seventeenth aspect enables an electronic device (100) to be produced such that transmission of heat generated from the heat generator (4) is further improved.

In a method of replacing a thermal conductive sheet in an electronic device of an eighteenth aspect of the present disclosure is a method of replacing a thermal conductive sheet (1) in an electronic device (100) including a heat generator (4), a heat radiator (3), a thermal conductive sheet (1), and an adhesive member (2). The thermal conductive sheet (1) lies between the heat generator (4) and the heat radiator (3). The adhesive member (2) lies between the thermal conductive sheet (1) and the heat generator (4) or the heat radiator (3). An adhesive force of the adhesive member (2) decreases along with a temperature rise. The method of replacing the thermal conductive sheet includes, after a temperature of the adhesive member (2) increased by heat generated by the heat generator (4) during use of the electronic device (100) reduces the adhesive force of the adhesive member (2), detaching the thermal conductive sheet (1) from the electronic device (100), and laying a new thermal conductive sheet (1) different from the thermal conductive sheet (1) between the heat generator (4) and the heat radiator (3).

The eighteenth aspect reduces the possibility that when the thermal conductive sheet (1) is to be detached from between the heat generator (4) and heat radiator (3), the thermal conductive sheet (1) remains on the front surface of the heat generator (4) or the heat radiator (3).

In a method of replacing a thermal conductive sheet in an electronic device according to a nineteenth aspect of the present disclosure referring to the eighteenth aspect, the heat generated by the heat generator (4) during the use of the electronic device (100) makes a temperature of the heat generator (4) reach a temperature higher than or equal to a temperature at which the adhesive force of the adhesive member (2) starts decreasing.

According to the nineteenth aspect, the heat generated by the heat generator (4) during the use of the electronic device (100) easily achieves a state where the adhesive member (2) is more easily peelable.

In a method of replacing of a thermal conductive sheet in an electronic device of a twentieth aspect of the present disclosure referring to the eighteenth or nineteenth aspect, the adhesive member (2) includes a base member (20), a first adhesive layer (21), and a second adhesive layer (22). The first adhesive layer (21) is stacked on a first surface (2a) of the base member (20). The second adhesive layer (22) is stacked on a second surface (2b) which is a surface on an opposite side of the base member (20) from the first surface (2a). An adhesive force of at least one of the first adhesive layer (21) or the second adhesive layer (22) decreases along with the temperature rise.

The twentieth aspect enables the adhesive member (2) to be easily peeled off from the heat generator (4) or the heat radiator (3), and therefore, the thermal conductive sheet (1) in the electronic device (100) is easily replaceable.

In a method of replacing of a thermal conductive sheet in an electronic device of a twenty-first aspect of the present disclosure referring to the twentieth aspect, the adhesive force of the first adhesive layer (21) decreases along with the temperature rise, and the second adhesive layer (22) is affixed to the thermal conductive sheet (1).

The twenty-first aspect reduces the possibility that when the thermal conductive sheet (1) is to be peeled off from the heat generator (4), the thermal conductive sheet (1) remains on the heat generator (4), and therefore, according to the twenty-first aspect, the thermal conductive sheet (1) in the electronic device (100) is easily replaceable.

In a method of replacing a thermal conductive sheet in an electronic device according to a twenty-second aspect of the present disclosure referring to any one of the eighteenth to twentieth aspects, the adhesive member (2) lies between the thermal conductive sheet (1) and the heat generator (4).

The twenty-second aspect reduces the possibility that when the thermal conductive sheet (1) is to be peeled off from the heat generator (4), the thermal conductive sheet (1) remains on the heat generator (4), and therefore, according to the twenty-second aspect, the thermal conductive sheet (1) in the electronic device (100) is easily replaceable.

In a method of replacing a thermal conductive sheet in an electronic device of a twenty-third aspect of the present disclosure referring to any one of the eighteenth to twenty-second aspects, peel strength of the adhesive member measured based on JIS Z0237 after the adhesive member is exposed to an atmosphere of 70° C. for 20 minutes is less than peel strength of the adhesive member at 25° C. by 75% or more.

According to the twenty-third aspect, when the thermal conductive sheet (1) is to be detached from between the heat generator (4) and the heat radiator (3), the thermal conductive sheet (1) is more easily detachable, and therefore, thermal conductive sheet (1) is more easily replaceable.

In a method of replacing a thermal conductive sheet in an electronic device in a twenty fourth aspect of the present disclosure referring to any one of the eighteenth to twenty-third aspects, the thermal conductive sheet (1) contains graphite.

According to the twenty-fourth aspect, heat transmission of the thermal conductive sheet (1) is further improved.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

1. A thermal conductive member comprising:
a thermal conductive sheet; and
an adhesive member stacked on a front surface of the thermal conductive sheet,
an adhesive force of the adhesive member decreasing along with a temperature rise.

2. The thermal conductive member of claim 1, wherein
the adhesive member includes
a base member,
a first adhesive layer stacked on a first surface of the base member, and
a second adhesive layer stacked on a second surface which is a surface on an opposite side of the base member from the first surface, and
an adhesive force of at least one of the first adhesive layer or the second adhesive layer decreases along with the temperature rise.

3. The thermal conductive member of claim 2, wherein
the adhesive force of the first adhesive layer decreases along with the temperature rise, and
the second adhesive layer is affixed to the thermal conductive sheet.

4. The thermal conductive member of claim 1, wherein
peel strength of the adhesive member measured based on JIS Z0237 after the adhesive member is exposed to an atmosphere of 70° C. for 20 minutes is less than peel strength of the adhesive member at 25° C. by 75% or more.

5. The thermal conductive member of claim 1, wherein
the thermal conductive sheet contains graphite.

6. An electronic device comprising:
a heat generator;
a heat radiator;
a thermal conductive sheet lying between the heat generator and the heat radiator; and
an adhesive member lying between the thermal conductive sheet and the heat generator or the heat radiator,
an adhesive force of the adhesive member decreasing along with a temperature rise.

7. The electronic device of claim 6, wherein
the adhesive member includes
a base member,
a first adhesive layer stacked on a first surface of the base member, and
a second adhesive layer stacked on a second surface which is a surface on an opposite side of the base member from the first surface, and
an adhesive force of at least one of the first adhesive layer or the second adhesive layer decreases along with the temperature rise.

8. The electronic device of claim 7, wherein
the adhesive force of the first adhesive layer decreases along with the temperature rise, and
the second adhesive layer is affixed to the thermal conductive sheet.

9. The electronic device of claim 6, wherein
the adhesive member lies between the thermal conductive sheet and the heat generator.

10. The electronic device of claim 6, wherein
peel strength of the adhesive member measured based on JIS Z0237 after the adhesive member is exposed to an atmosphere of 70° C. for 20 minutes is less than peel strength of the adhesive member at 25° C. by 75% or more.

11. The electronic device of claim 6, wherein
the thermal conductive sheet contains graphite.

12. A method of manufacturing an electronic device including a heat generator, a heat radiator, and a thermal conductive sheet lying between the heat generator and the heat radiator, the method comprising laying an adhesive member between the thermal conductive sheet and the heat generator or the heat radiator, an adhesive force of the adhesive member decreasing along with a temperature rise.

13. The method of claim 12, wherein
the adhesive member includes
a base member,
a first adhesive layer stacked on a first surface of the base member, and
a second adhesive layer stacked on a second surface which is a surface on an opposite side of the base member from the first surface, and
an adhesive force of at least one of the first adhesive layer or the second adhesive layer decreases along with the temperature rise.

14. The method of claim 13, wherein
the adhesive force of the first adhesive layer decreases along with the temperature rise, and
the second adhesive layer is affixed to the thermal conductive sheet.

15. The method of claim 12, wherein
the adhesive member is laid between the thermal conductive sheet and the heat generator.

16. The method of claim 12 manufacturing, wherein
peel strength of the adhesive member measured based on JIS Z0237 after the adhesive member is exposed to an atmosphere of 70° C. for 20 minutes is less than peel strength of the adhesive member at 25° C. by 75% or more.

17. The method of claim 12, wherein
the thermal conductive sheet contains graphite.

18. A method of replacing a thermal conductive sheet in an electronic device including a heat generator, a heat radiator, the thermal conductive sheet lying between the heat generator and the heat radiator, and an adhesive member lying between the thermal conductive sheet and the heat generator or the heat radiator, an adhesive force of the adhesive member decreasing along with a temperature rise, the method comprising:
after a temperature of the adhesive member increased by heat generated by the heat generator during use of the electronic device reduces the adhesive force of the adhesive member, detaching the thermal conductive sheet from the electronic device; and
laying a new thermal conductive sheet different from the thermal conductive sheet between the heat generator and the heat radiator.

19. The method of claim 18, wherein
the heat generated by the heat generator during the use of the electronic device makes a temperature of the heat generator reach a temperature higher than or equal to a temperature at which the adhesive force of the adhesive member starts decreasing.

20. The method of claim 18, wherein
the adhesive member includes
a base member,
a first adhesive layer stacked on a first surface of the base member, and
a second adhesive layer stacked on a second surface which is a surface on an opposite side of the base member from the first surface, and
an adhesive force of at least one of the first adhesive layer or the second adhesive layer decreases along with the temperature rise.

21. The method of claim 20, wherein
the adhesive force of the first adhesive layer decreases along with the temperature rise, and
the second adhesive layer is affixed to the thermal conductive sheet.

22. The method of claim 18, wherein
the adhesive member lies between the thermal conductive sheet and the heat generator.

23. The method of claim 18, wherein
peel strength of the adhesive member measured based on JIS Z0237 after the adhesive member is exposed to an atmosphere of 70° C. for 20 minutes is less than peel strength of the adhesive member at 25° C. by 75% or more.

24. The method of claim 18, wherein
the thermal conductive sheet contains graphite.
